(19) United States
(12) Patent Application Publication
(10) Pub. No.: US 2024/0063445 A1
(43) Pub. Date: Feb. 22, 2024

(54) Cell Contacting System, Method for Producing a Cell Contacting System and Battery Module

(71) Applicant: TE Connectivity Germany GmbH, Bensheim (DE)

(72) Inventor: Thorsten Callies, Bensheim (DE)

(73) Assignee: TE Connectivity Germany GmbH, Bensheim (DE)

(21) Appl. No.: 18/451,173

(22) Filed: Aug. 17, 2023

(30) Foreign Application Priority Data
Aug. 17, 2022 (DE) 102022120806.0

(51) Int. Cl. H01M 10/42; H01M 50/569; H01M 10/48; G01R 31/3842

(52) U.S. Cl. CPC H01M 10/4285; H01M 50/569; H01M 10/486; H01M 10/482; G01R 31/3842

(57) ABSTRACT

A cell contacting system for an electrical battery module includes a carrier structure, a plurality of cell contacting elements arranged on the carrier structure and electrically contacting a plurality of battery cells, a plurality of power connections electrically connected to the cell contacting elements, and a measuring arrangement measuring a parameter of the electrical battery module. The measuring arrangement has a sensor element connected to a connection contact of the cell connecting system via a sensor line. A monitoring device is connectable to the measuring arrangement via the connection contact in order to monitor the parameter. The sensor element is connected to at least one of the cell contacting elements and measures the parameter. The sensor element is fastened on the at least one of the cell contacting elements by a retaining element formed on the at least one of the cell contacting elements.

### CROSS-REFERENCE TO RELATED APPLICATIONS

This application claims the benefit of the filing date under 35 U.S.C. § 119(a)-(d) of German Patent Application No. 102022120806.0, filed on Aug. 17, 2022.

### FIELD OF THE INVENTION

The invention relates to a cell contacting system for an electrical battery module, a method for producing a cell contacting system, and a battery module having a cell contacting system.

### BACKGROUND

Various embodiments of cell contacting systems for electrical battery modules are known from the prior art. Cell contacting systems serve to bring about the flow of current from and to the individual battery cells of the battery module. Furthermore, cell contacting systems serve to enable monitoring of parameters, such as the operating voltage and/or the operating temperature, of the battery module.

### SUMMARY

A cell contacting system for an electrical battery module includes a carrier structure, a plurality of cell contacting elements arranged on the carrier structure and electrically contacting a plurality of battery cells, a plurality of power connections electrically connected to the cell contacting elements, and a measuring arrangement measuring a parameter of the electrical battery module. The measuring arrangement has a sensor element connected to a connection contact of the cell connecting system via a sensor line. A monitoring device is connectable to the measuring arrangement via the connection contact in order to monitor the parameter. The sensor element is connected to at least one of the cell contacting elements and measures the parameter. The sensor element is fastened on the at least one of the cell contacting elements by a retaining element formed on the at least one of the cell contacting elements.

### BRIEF DESCRIPTION OF THE DRAWINGS

The invention is explained in more detail below with the aid of the figures, in which:

FIG. 1 is a schematic illustration of a cell contacting system according to an embodiment;

FIG. 2 is a schematic illustration of a retaining element of the cell contacting system according to an embodiment;

FIG. 3 is a schematic illustration of the retaining element in FIG. 2 with a sensor element;

FIG. 4 is a schematic illustration of a retaining element of the cell contacting system according to a further embodiment;

FIG. 5 is a schematic illustration of the retaining element in FIG. 4 with a sensor element;

FIG. 6 is a schematic illustration of a retaining element of the cell contacting system according to a further embodiment with a sensor element;

FIG. 7 is a schematic illustration of a retaining element of the cell contacting system according to a further embodiment with a sensor element;

FIG. 8 is a schematic illustration of a sensor element, designed as a temperature sensor, according to an embodiment;

FIG. 9 is a schematic illustration of a sensor element, designed as a temperature sensor, according to a further embodiment;

FIG. 10 is a schematic illustration of the sensor element of FIG. 9 fastened on a retaining element;

FIG. 11 is a further schematic illustration of the sensor element of FIG. 9 fastened on a retaining element;

FIG. 12 is a schematic sectional side view of the sensor element of FIG. 11;

FIG. 13 is a flow chart of a method for producing a cell contacting system; and

FIG. 14 is a schematic illustration of a battery module having a cell contacting system.

### DETAILED DESCRIPTION OF THE EMBODIMENT(S)

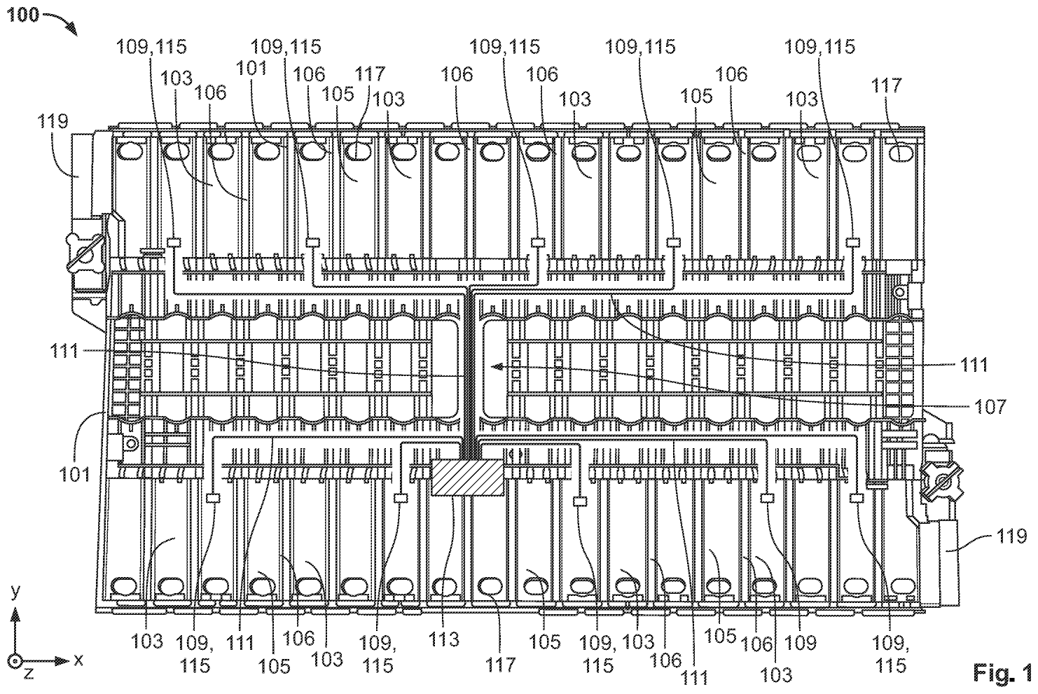

FIG. 1 is a schematic illustration of a cell contacting system 100 according to an embodiment. In the embodiment shown, the cell contacting system 100 has a carrier structure 101 and a multiplicity of cell contacting elements 103 formed on the carrier structure 101. The carrier structure 101 may be made from an electrically insulating material, for example plastic.

The cell contacting elements 103 serve for electrical contacting of a multiplicity of battery cells of a battery module connected to the cell contacting system 100. The cell contacting elements 103 are made from a metal material. The cell contacting elements 103 each have multiple cell elements 105. A cell element 105 here serves for contacting of a battery cell. The individual cell elements 105 each have connecting openings 117 for connecting and fastening the battery cells, for example via a screw connection.

The individual cell elements 105 are separated from one another in each case by separating elevations 106. The individual cell contacting elements 103 may be manufactured, for example, from sheet metal elements. The separating elevations 106 may be formed via corresponding bending or shaping processes here.

The cell contacting elements 103 are electrically connected to one another and to a multiplicity of power connections 119. A battery module connected to the cell contacting system 100 can be connected to further battery modules or to further electrical components via the power connections 119.

According to an embodiment, the cell contacting system 100 is designed for a battery module of an electric vehicle. The battery module connected to the cell contacting system 100 can therefore be connected to further components of the electric vehicle via the power connections 119.

In the embodiment shown, the cell contacting system 100 furthermore comprises a measuring arrangement 107. The measuring arrangement 107 serves for measuring a parameter of the battery module connected to the cell contacting system 100. A functionality of the battery module can therefore be monitored or checked via the measurement of the parameter.

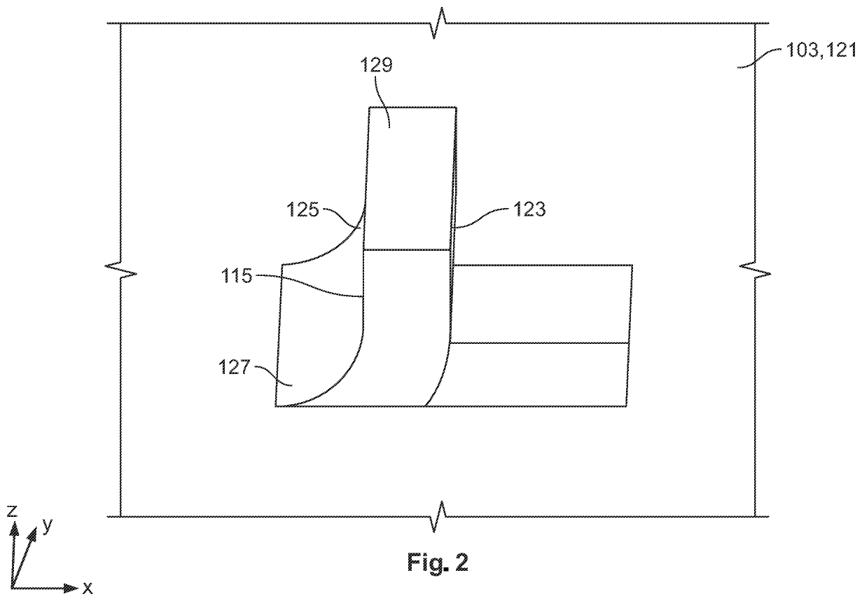

To measure the parameter, the measuring arrangement 107 has at last one sensor element 109, which is configured to measure the parameter. To this end, the at least one sensor element 109 is connected to the respective cell contacting element 103, or fastened thereon, via a retaining element 115 formed on at least one cell contacting element 103. The retaining elements 115 are not shown in detail in FIG. 1. For a detailed description of the retaining elements 115, please refer to the following FIGS. 2-12 and the associated parts of the description.

In the embodiment shown, the measuring arrangement 107 has a multiplicity of sensor elements 109. The sensor elements 109 here are each formed on the cell contacting elements 103 in such a way that only one sensor element 109 in each case is arranged on a cell contacting element 103.

The parameters to be measured may be an operating voltage or an operating temperature of the battery module. The sensor elements 109 are therefore configured to measure a voltage or temperature of the cell contacting elements 103.

In the embodiment shown, the multiple sensor elements 109 are electrically connected to a connection contact 113 via sensor lines 111. The measuring arrangement 107 and, in particular, the sensor elements 109 may be connected to a monitoring device via the connection contact 113. The monitoring device may comprise, for example, an arithmetic unit on which software is installed, by means of which the parameters and, consequently, the functionality of the battery module connected to the cell contacting system 100 may be monitored or checked. The sensor lines 111 may be designed as standard electrical cables.

The sensor elements 109 may be fastened to the retaining elements 115 via welded connections or bonded connections.

The number of cell contacting elements 103 of a cell contacting system 100 may be different from the number shown in FIG. 1. Each cell contacting element 103 may also have a number of cell elements 105 which differs from the number shown in FIG. 1. Furthermore, the measuring arrangement 107 may have any number of sensor elements 109 which differs from the number in FIG. 1. The sensor elements 109 may also be formed at any points on the respective cell contacting elements 103.

Each sensor element 109 may be connected to the connection contact via an individual sensor line 111 in each case. Alternatively, multiple sensor elements 109 may be connected to the connection contact 113 via a common sensor line 111.

FIG. 2 shows a schematic illustration of a retaining element 115 of the cell contacting system 100 according to an embodiment. In the embodiment shown, the retaining element 115 comprises a bent element 125. The bent element 125 comprises a bent portion 127 and a contact portion 129 having a contacting area 123. The bent element 125 is connected to a respective cell contacting element 103 via the bent region 127. In the embodiment shown, the retaining element 115 is manufactured from the respective cell contacting element 103 via a punching and bending process.

In the embodiment shown, the contacting area 123 is arranged at a spacing from a surface 121 of the respective cell contacting element 103. The contacting area 123 serves for the contacting of the retaining element 115 by a corresponding sensor element 109.

The contacting area 123 in the embodiment shown is arranged at a right angle to the surface 121 of the cell contacting element 103. However, the contacting area 123 may also be at any other angle to the surface 121.

In the embodiment shown, the contacting portion 129 has a cuboidal form. However, this is only illustrative. Other forms are likewise conceivable.

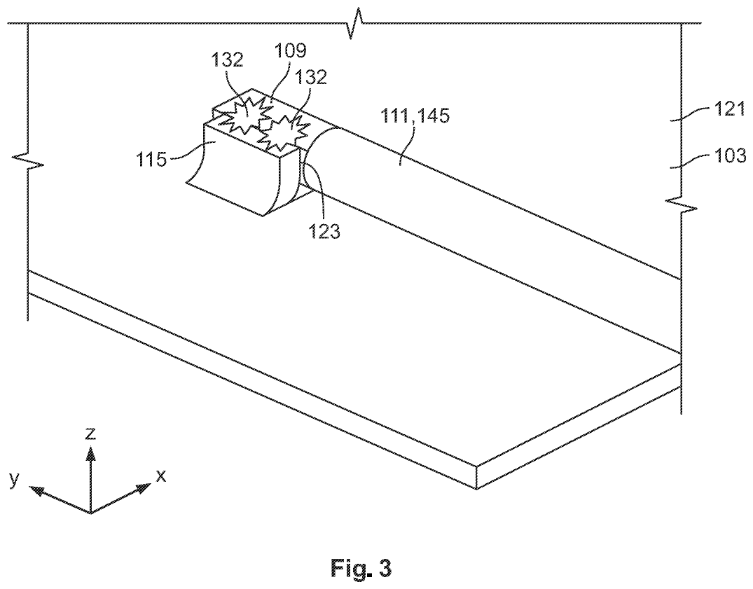

FIG. 3 shows a further schematic illustration of the retaining element 115 in FIG. 2 with a sensor element 109. In the embodiment shown, the sensor element 109 is fastened on the retaining element 115 via a welded connection 132. The sensor element 109 is arranged adjacent to the retaining element 115, with reference to the x axis of the illustrated coordinate system, and contacts the retaining element 115 via the contacting area 123. The welded connection 132 is formed by two welded points in an upper region of the contact portion 129 of the bent element 125, with reference to the z axis.

The sensor element 109 in the embodiment shown is designed as a compacted end region of the sensor line 111. Alternatively, the sensor element 109 may be designed as a bunch of stranded wires or a cable end sleeve.

An operating voltage of a battery module connected to the cell contacting system 100 can be measured by the sensor element 109 shown, via the electrical contacting with the retaining element 115.

The sensor line 11 in the embodiment shown is designed as a commercially available electrically conductive cable with insulation 145.

As a result of the spacing of the contacting area 123 from the surface 121 of the cell contacting element 103, the sensor element 109 fastened on the contacting area 123 may likewise be arranged at a spacing from the surface 121. Differences in thickness between the sensor line 111 and the sensor element 109, which may be caused by the insulation 145, for example, may therefore be compensated.

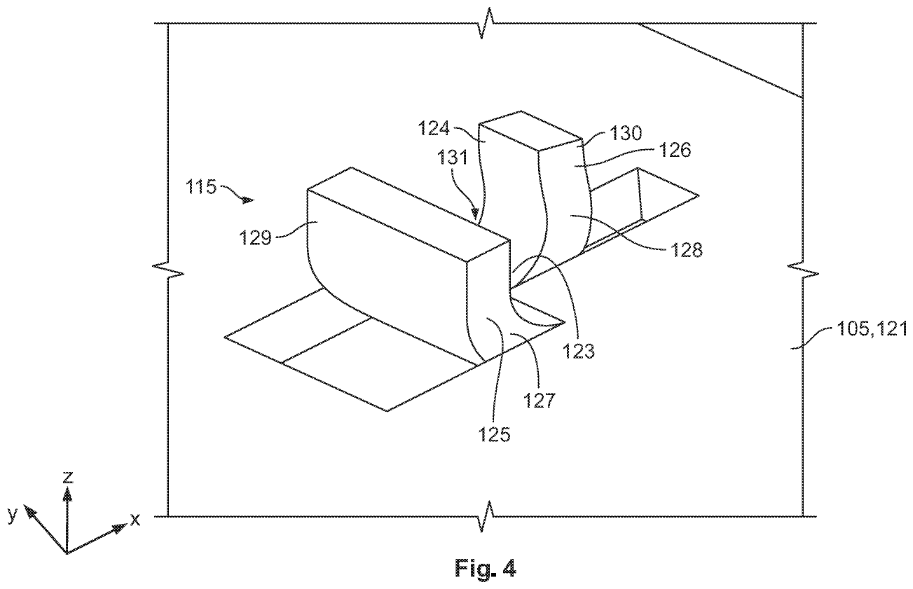

FIG. 4 shows a schematic illustration of a retaining element 115 of the cell contacting system 100 according to a further embodiment. In the embodiment shown, in addition to the bent element 125 of the embodiment in FIGS. 2 and 3, the retaining element 115 comprises a further bent element 126, which is arranged opposite the bent element 125 with reference to the x axis. The further bent element 126 comprises a further bent portion 128 and a further contact portion 130 having a contacting area 124.

The two contacting areas 123, 124 are arranged opposite and facing one another with reference to the x axis. The two contacting areas 123, 124 are substantially parallel to one another and formed at a right angle to the surface 121 of the cell contacting element 103. A receiving space 131 for receiving a sensor element 109 is defined between the two bent elements 125, 126 and, in particular, between the two contacting areas 123, 124.

In the embodiment shown, both bent elements 125, 126 are formed from the cell contacting element 103 via a punching and bending process. In the embodiment shown, the further bent element 126 is formed with smaller dimensions than the bent element 125. Alternatively, both bent elements 125, 126 may have the same form and the same dimensions.

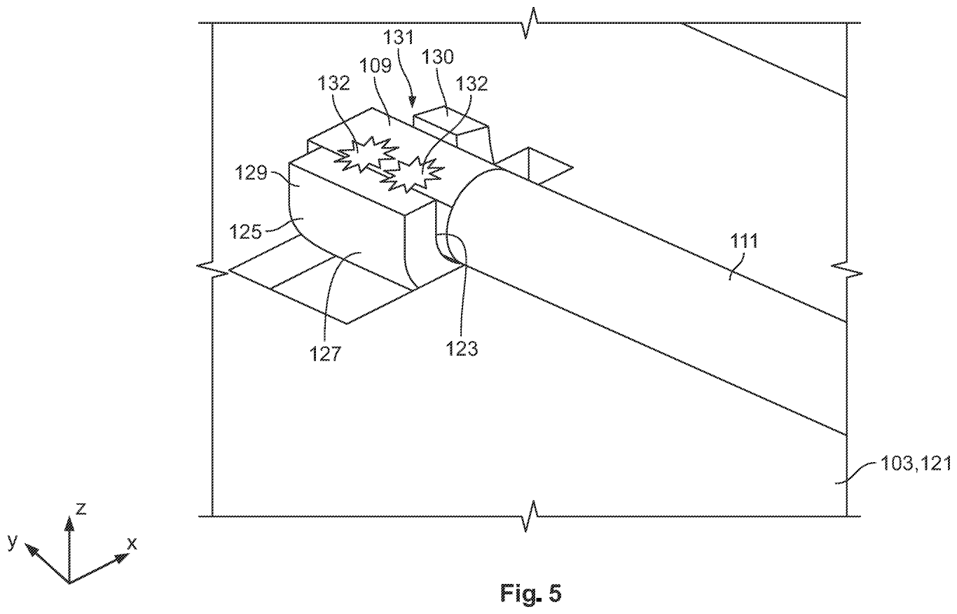

FIG. 5 shows a schematic illustration of the retaining element 115 in FIG. 4 with a sensor element 109. In FIG. 5, the sensor element 109 is inserted into the receiving space 131 of the retaining element 115 and consequently electrically connected to the two contacting areas 123, 124 of the two bent elements 125, 126. The sensor element 109 is clamped in the receiving space 131 between the two contacting areas 123, 124 via the two bent elements 125, 126. The two bent elements 125, 126 are configured to exert opposing restoring forces on the sensor element 109, which is inserted into the receiving space 131, via the bent portions 127, 128.

Furthermore, the sensor element is fastened on the contact portion 129 of the bent element 125 via welded connections 132, analogously to the embodiment in FIG. 3. Alternatively, the sensor element 109 may be fastened on the further contact portion 130 of the further bent element 126 or on both bent elements 125, 126 via welded connections.

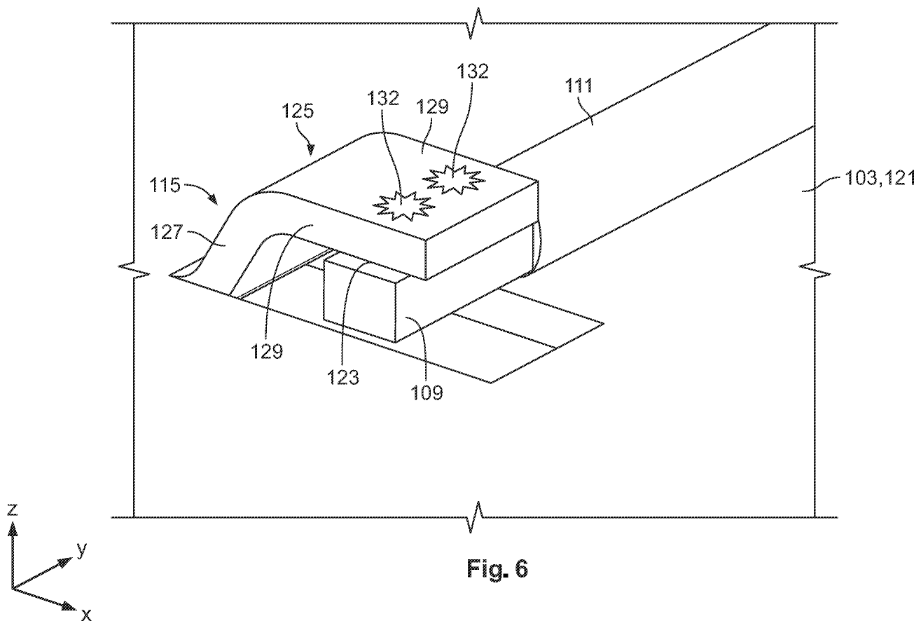

FIG. 6 shows a further schematic illustration of a retaining element 115 of the cell contacting system 100 according to a further embodiment with a sensor element 109. In the embodiment shown, the retaining element 115 in turn comprises only one bent element 125 having a bent portion 127 and a contact portion 129 with a contacting area 123. In the embodiment shown, the contacting area 123 is arranged parallel or virtually parallel to the surface 121 of the cell contacting element 103. The contacting area 123 is spaced from the surface 121 and facing it. A sensor element 115 is fastened on the contacting area 123 by a welded connection 132. The sensor element 109 is therefore arranged in a space between the surface 121 of the cell contacting element 103 and the contacting area 123. The welded points of the welded connection 132 are formed on an area of the contact portion 129 of the bent element 125 which is arranged opposite the contacting area 123.

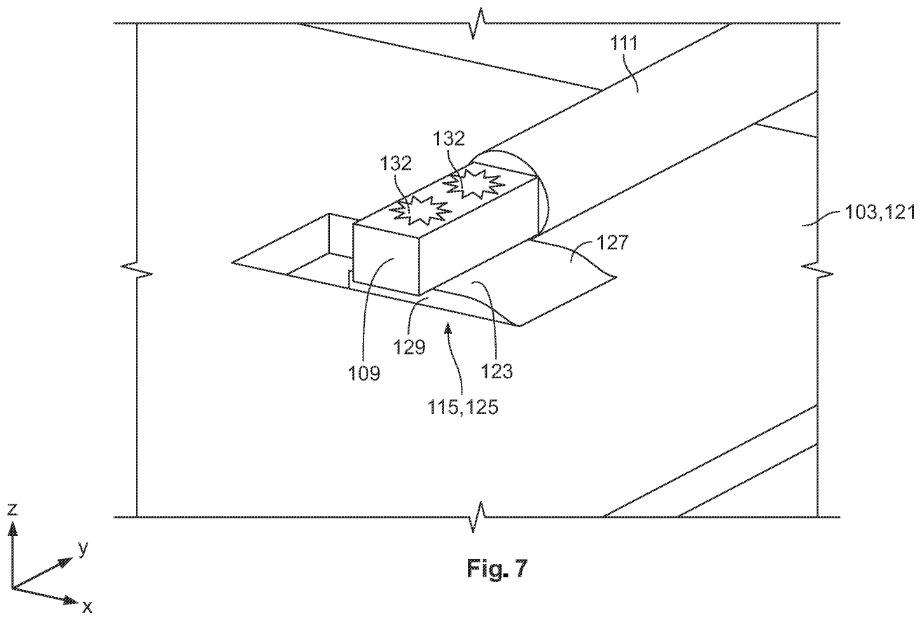

FIG. 7 shows a further schematic illustration of a retaining element 115 of the cell contacting system 100 according to a further embodiment with a sensor element 109. The embodiment shown is based on the embodiment in FIG. 6. In a departure from the embodiment shown in FIG. 6, in this embodiment, the contacting area 123 is in turn arranged parallel or virtually parallel to the surface 121 of the cell contacting element 103, but facing away from the surface 121. The sensor element 109 is therefore arranged such that it lies on the contacting area 123 with reference to the z axis and is fastened on the retaining element 115 via a welded connection. Moreover, the contacting area 123 is at a smaller spacing away from the surface 121 than in the embodiment of FIG. 6.

In the above-described embodiments, the contact portions each have a cuboidal form. Alternatively, other forms are also conceivable. The size and form of the contacting areas 123, 124 may vary depending on the application and design of the sensor element 109.

The sensor elements 109 in the embodiments shown are formed from compacted cuboidal portions of end pieces of the cable of the sensor line 111. Alternatively, bunches of stranded wires or cable end sleeves are likewise conceivable as sensor elements 109 for measuring the operating voltage.

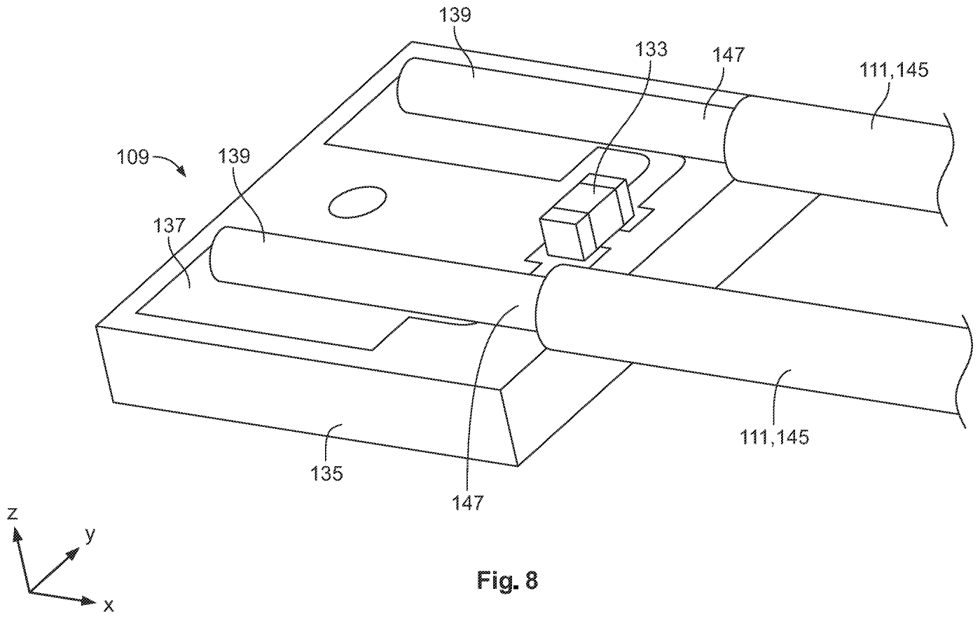

FIG. 8 shows a schematic illustration of a sensor element 109, designed as a temperature sensor 133, according to an embodiment. In the embodiment shown, the sensor element 109 comprises a temperature sensor 133 for measuring an operating temperature of a battery module connected to the cell contacting system 100. The sensor element 109 here comprises a printed circuit board 135 with contacting fields 137 for electrically contacting the temperatures sensor 133 by at least one sensor line 111. In the embodiment shown, the temperature sensor 133 is electrically connected to two sensor lines 111 via the contacting fields 137.

Analogously to the above-described embodiments, the sensor lines 111 are designed as standard electrically conductive cables with insulation 145 and have connection elements 139, which, by way of example, are realized by non-insulated portions 147 and via which the sensor lines 111 are connected to the contacting fields 137 in an electrically conductive manner, for example via a soldered connection.

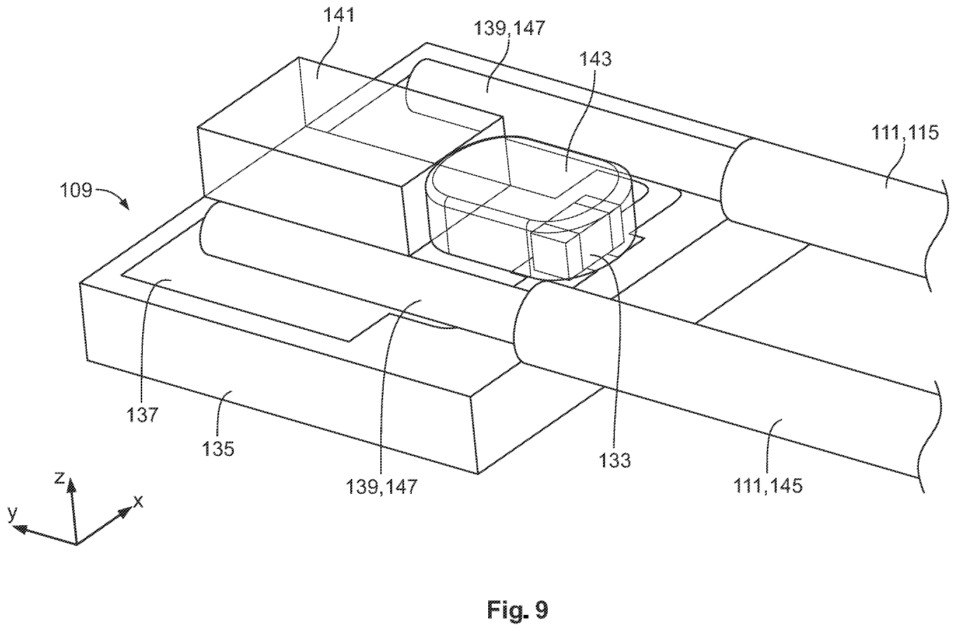

FIG. 9 shows a further schematic illustration of a sensor element 109, designed as a temperature sensor 133, according to a further embodiment. The embodiment shown is based on the embodiment in FIG. 8. In the embodiment shown, a spacer element 141 is furthermore formed on the printed circuit board 135, between the two sensor lines 111. The spacer element 141 has a greater height than the temperature sensor 133 with reference to the z axis.

The spacer element 141 has a cuboidal form in the embodiment shown in FIG. 9. Other forms are likewise possible. The dimensions of the spacer element 141 can be adapted accordingly to the requirements and designs of the temperature sensor 133. However, one prerequisite is that the spacer element 141 has a greater height than the temperature sensor 133 with reference to the z axis aligned perpendicularly to a surface of the printed circuit board 135.

In the embodiment shown in FIG. 9, the sensor element 109 furthermore has a potting compound 143, which is arranged on the printed circuit board 135, covering the temperature sensor 133. The potting compound 143 may be formed from a potting material known from the prior art, for example from a silicone or polyurethane compound.

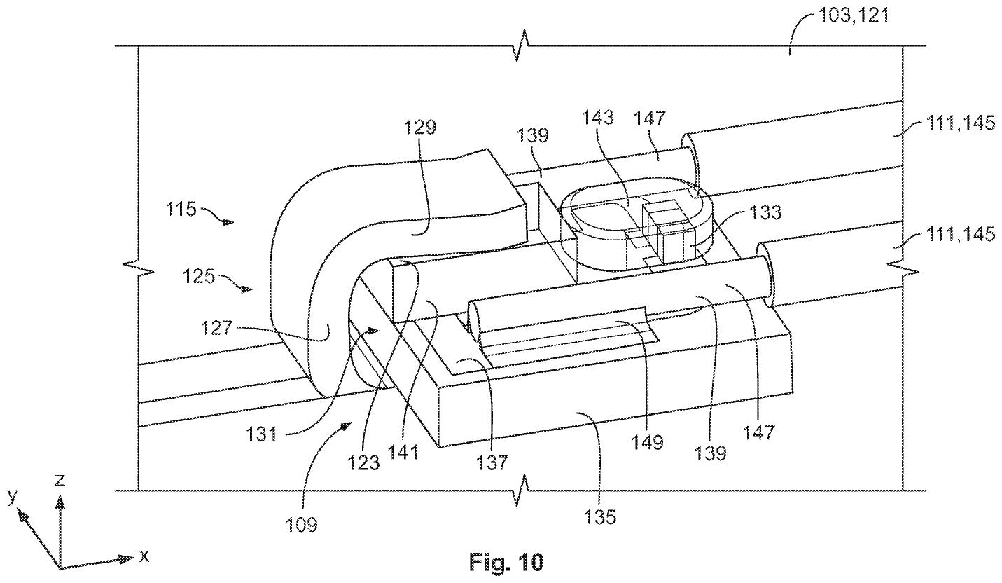

FIG. 10 shows a schematic illustration of the sensor element 109 of FIG. 9, fastened on a retaining element 115. In the embodiment shown, analogously to the above-described embodiments of FIGS. 6 and 7, the retaining element 115 has a bent element 125 having a bent portion 127 and a contact portion 129 with a contacting area 123. The contacting area 123 is formed parallel to the surface 121 of the cell contacting element 103 and facing the surface 121. A receiving space 131 for receiving the sensor element 109 is defined between the surface 121 and the contacting area 123.

The sensor element 109 is inserted into the receiving space 131 in such a way that the spacer element 141 contacts the contacting area 123. Via the bent portion 127 of the bent element 125, the retaining element 115 is capable of exerting a restoring force on the spacer element 141 via the contacting portion 129 and therefore clamping the sensor element 109 in the receiving space 131 and fastening it on the retaining element 115.

In the embodiment shown, by soldered connections 149, the sensor lines 111 are electrically connected to the contacting fields 137 via corresponding connection portions 139, which, in the example shown, are formed by the non-insulated portions 147 of the cable.

According to an embodiment, the temperature sensor 133 may furthermore be connected to the cell contacting element 103 in a thermally conductive manner via a bonded connection. The thermal connection may be established directly via the surface 121 of the cell contacting element 103. Alternatively or additionally, thermal contacting between the temperature sensor 133 and the retaining element 115 may occur and may be established in particular via the contacting area 123 of the contact portion 129.

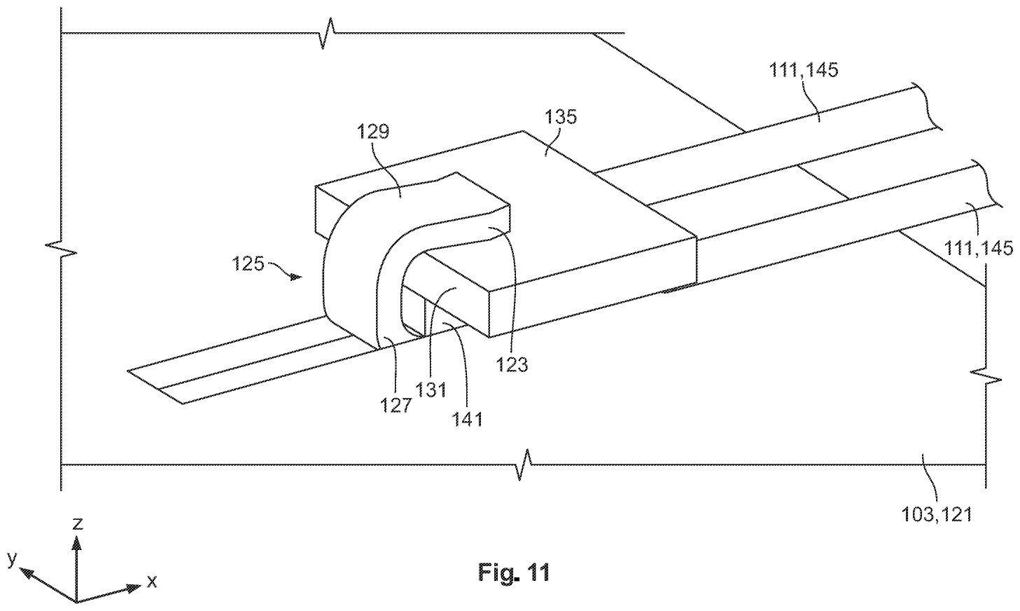

FIG. 11 shows a further schematic illustration of the sensor element 109 of FIG. 9, fastened on a retaining element 115. The embodiment shown in FIG. 11 is based on the embodiment in FIG. 10 and differs from this in that the sensor element 109 is arranged in a mirror-inverted manner in the receiving space 131 of the bent element 125 with reference to the z axis. An underside of the printed circuit board 135 contacts the contacting area 123 of the bent element 125 here, whilst the spacer element 141 contacts the surface 121 of the cell contacting element 103. The clamping of the sensor element 109 in the receiving space 129 of the bent element 125 is realized analogously to the embodiment in FIG. 10.

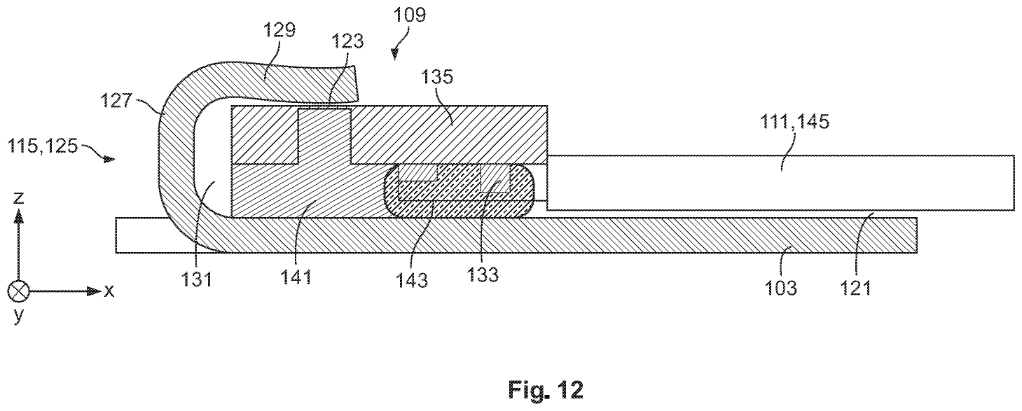

FIG. 12 shows a schematic sectional side view of the sensor element 109 of FIG. 11. It is shown in FIG. 12 that the spacer element 141 extends at least partially through the printed circuit board. The spacer element 141 thereby contacts both the surface 121 of the cell contacting element 103 and the contacting area 123 of the bent element 125 or the retaining element. The potting element 143 likewise contacts the surface 121 of the cell contacting element 103. The temperature sensor 133, on the other hand, remains at a spacing from the surface 121 of the cell contacting element 103 so that it is possible to avoid damage to the temperature sensor as a result of clamping the sensor element 109 in the receiving space 131 of the retaining element 115.

In all embodiments shown, the temperature sensor 133 may furthermore be brought into thermal contact with the cell contacting element 103 via a bonded connection. The temperature sensor 133 may be formed for example by a thermistor.

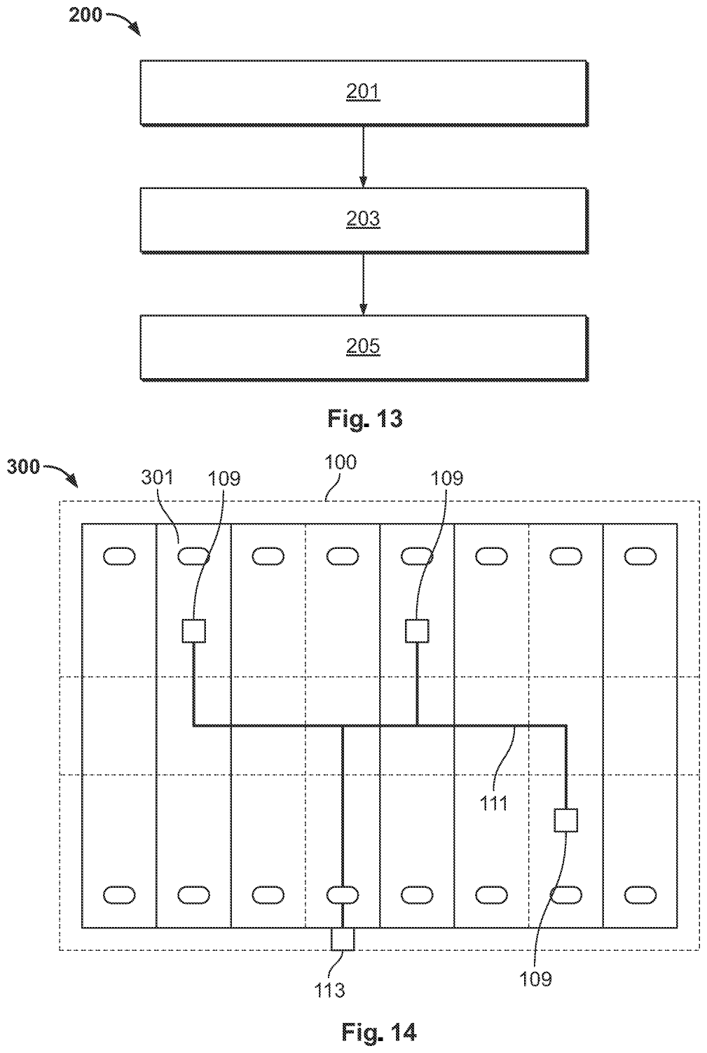

FIG. 13 shows a flow chart of a method 200 for producing a cell contacting system 100.

In a first method step 201, a cell contacting system 100 according to one of the above-described embodiments is firstly provided. The cell contacting system 100 comprises a carrier structure 100 having a multiplicity of cell contacting elements 103. At least one retaining element 115 according to the above-described embodiments is formed on at least one cell contacting element 103. The provision 201 of the cell contacting system 100 may therefore comprise a punching and bending process for forming the at least one retaining element 115 from the at least one cell contacting element 103.

In a further method step 203, at least one sensor element 109 is arranged on the at least one retaining element 115. To this end, according to the above-described embodiments, the sensor element 109 may be placed on a contacting area 123 of the retaining element 115. To this end, the sensor element 109 may be positioned on the contacting area 123 or inserted into a receiving space 131 and clamped on the cell contacting element 103 by the retaining element 115.

After arranging or fastening the sensor element 109 on the retaining element 115, the sensor element 109 may be fastened on the retaining element 115, and therefore on the cell contacting element 103, via a welded connection or a bonded connection. It is thereby possible to achieve an electrical and/or thermal connection of the sensor element 109 to the cell contacting element 103.

According to the above-described embodiments, the sensor element 109 may be designed to measure an operating voltage of a battery module connected to the cell contacting system 100. Alternatively, the sensor element 109 may be configured to measure an operating temperature of the battery module. To this end, the sensor element 109 may comprise a temperature sensor 133 according to the above-described embodiments.

In a further method step 205, the at least one sensor element 109 arranged or fastened on the retaining element 115 may be electrically connected to a connection contact 113 via a sensor line 111. The sensor line 111 here may be realized by a standard and commercially available electrical cable. The connection contact 113 formed on the carrier structure 101 enables electrical connection of a monitoring device to the cell contacting system 100. The monitoring device is designed to monitor the parameters of the battery module which are described by the operating voltage and/or the operating current.

The monitoring device may comprise a corresponding processor, for example, on which corresponding software is installed for monitoring and evaluating the parameter.

FIG. 14 shows a schematic illustration of a battery module 300 having a cell contacting system 100. The battery module 300 comprises a multiplicity of battery cells 301. The cell contacting system 100 is electrically connected to the multiplicity of battery cells 301 via the multiplicity of cell contacting elements 103. The connection may be achieved, for example, via screw connections through the connecting openings 117 of the cell contacting elements 103. The cell contacting system 100 furthermore has a measuring arrangement 107 having a multiplicity of sensor elements 109 arranged on the cell contacting elements 103 in order to measure a parameter of the battery module 300. The sensor elements 109 are connected to a connection contact 113 via sensor lines 111.

The individual battery cells 301 of the battery module 300 are connected to one another via the cell contacting elements 103 of the cell contacting system 100. The battery cells 301 may be connected to one another both in series and in parallel via the cell contacting system 100.

The battery module 300 may be designed, in particular, as a battery module 300 for an electric vehicle.

As a result of the measuring arrangement, a technically simple solution for measuring a parameter may be realized, by which the functionality and performance of the battery module may be monitored. Since the sensor elements may be wired and connected to the connection contact using standard cables, it is possible to avoid substantially more technically complex solutions, known from the prior art, which provide printed circuit boards (PCB) and ribbon cables for the electrical connection of the sensor elements and the connection contact. A technically simpler and therefore more cost-effective solution is thus enabled.

As a result of the retaining elements on the cell contacting elements, simplified contacting and fastening of the sensor elements on the cell contacting elements is enabled. As a result of the arrangement of the sensor elements on the cell contacting elements, a manufacturing process for the cell contacting system is also simplified and therefore improved.

What is claimed is:

1. A cell contacting system for an electrical battery module, comprising:
a carrier structure;
a plurality of cell contacting elements arranged on the carrier structure and electrically contacting a plurality of battery cells of the electrical battery module;
a plurality of power connections electrically connected to the cell contacting elements; and
a measuring arrangement measuring a parameter of the electrical battery module connected to the cell contacting system, the measuring arrangement has a sensor element connected to a connection contact of the cell connecting system via a sensor line, a monitoring device is connectable to the measuring arrangement via the connection contact in order to monitor the parameter, the sensor element is connected to at least one of the cell contacting elements and measures the parameter, the sensor element is fastened on the at least one of the cell contacting elements by a retaining element formed on the at least one of the cell contacting elements.

2. The cell contacting system of claim 1, wherein the retaining element is a clip element.

3. The cell contacting system of claim 2, wherein the clip element clamps the sensor element on the at least one of the cell contacting elements.

4. The cell contacting system of claim 1, wherein the retaining element defines a contacting area contacting the sensor element.

5. The cell contacting system of claim 4, wherein the contacting area is formed at a spacing from a surface of the at least one of the cell contacting elements.

6. The cell contacting system of claim 1, wherein the retaining element defines a receiving space receiving the sensor element.

7. The cell contacting system of claim 6, wherein the sensor element is inserted into the receiving space to fasten the sensor element on the retaining element.

8. The cell contacting system of claim 1, wherein the parameter is an electrical voltage or an electrical current.

9. The cell contacting system of claim 8, wherein the sensor element is an electrical contact element of the sensor line.

10. The cell contacting system of claim 9, wherein the sensor element is fastened on the retaining element via a welded connection.

11. The cell contacting system of claim 1, wherein the parameter is a temperature and the sensor element is a temperature sensor.

12. The cell contacting system of claim 11, wherein the sensor element is fastened on the at least one of the cell contacting elements in a thermally conductive manner by the retaining element.

13. The cell contacting system of claim 12, wherein the temperature sensor is arranged on a printed circuit board.

14. The cell contacting system of claim 13, wherein a spacer element is formed on the printed circuit board, the temperature sensor is fastened on the at least one of the cell contacting elements by pressing the retaining element on the spacer element.

15. The cell contacting system of claim 12, wherein the temperature sensor is contacted by the retaining element in a thermally conductive manner via a bonded connection.

16. The cell contacting system of claim 12, wherein the temperature sensor is contacted by a surface of the at least one of the cell contacting elements in a thermally conductive manner via a bonded connection.

17. The cell contacting system of claim 1, wherein the retaining element is formed on the at least one of the cell contacting elements via a punching and bending process.

18. A method for producing a cell contacting system, comprising:
providing a carrier structure having a plurality of cell contacting elements, at least one of the cell contacting elements has a retaining element;
fastening a sensor element of a measuring arrangement on the retaining element; and
connecting the sensor element to a connection contact of the carrier structure via a sensor line.

19. A battery module, comprising:
a plurality of battery cells; and
a cell contacting system including a carrier structure, a plurality of cell contacting elements arranged on the carrier structure and electrically contacting the plurality of battery cells, a plurality of power connections electrically connected to the cell contacting elements, and a measuring arrangement measuring a parameter of the battery module, the measuring arrangement has a sensor element connected to a connection contact of the cell connecting system via a sensor line, a monitoring device is connectable to the measuring arrangement via the connection contact in order to monitor the parameter, the sensor element is connected to at least one of the cell contacting elements and measures the parameter, the sensor element is fastened on the at least one of the cell contacting elements by a retaining element formed on the at least one of the cell contacting elements.
